(19) United States
(12) Patent Application Publication
(10) Pub. No.: US 2003/0063561 A1
(43) Pub. Date: Apr. 3, 2003

(54) Equivalent switching method for transmission devices in mpls networks

(76) Inventor: Joachim Klink, Muenchen (DE)

Correspondence Address: MORRISON & FOERSTER LLP, 1650 TYSONS BLVD. - SUITE 300, MCLEAN, VA, 22102, US

(21) Appl. No.: 10/203,817

(22) PCT Filed: Jan. 12, 2001
(86) PCT No.: PCT/EP01/00340

(30) Foreign Application Priority Data
Feb. 15, 2000 (EP) 00103082.4

(51) Int. Cl. G01R 31/08

(52) U.S. Cl. 370/228; 370/227

(57) ABSTRACT

In prior art, equivalent switching of MPLS packets can result in maloperations. The inventive method provides a solution to the problem in the following manner: when a working entity fails, equivalent switching is controlled in accordance with priority criteria and logical link information for one single protection entity.

The invention relates to a method according to the preamble of patent claim 1.

A method for the protection switching of transmission devices is already known from German patent specification DE 196 46 016 C2.

This known method relates to transmission devices via which information is conducted in accordance with an asynchronous transfer mode (ATM). In this arrangement, a transmission device for the bidirectional transmission of digital signals is provided in which two switching devices acting as terminal stations are connected to one another via an operating link and a protection link. The two terminal stations in each case contain a monitoring device for detecting transmission faults. A switching system, which can be controlled by the monitoring device, connects a receiving device to the operating link in a first switching state and to the protection link in a second switching state.

The disadvantageous factor of this known method is that it relates exclusively to ATM transmission devices. In the Internet, information is supplied to the receiving subscriber via a multiplicity of network nodes which can be constructed as routers. Between the routers, MPLS networks can be arranged. However, there is no mention of MPLS networks in the known method.

The invention is based on the object of developing a method of the type initially mentioned in such a manner that information can be transmitted with great reliability via a plurality of network nodes even in the Internet.

The invention is achieved, on the basis of the features specified in the preamble of patent claim 1, by its characterizing features.

It is particularly advantageous in the invention that the MPLS packets are additionally conducted via the protection link, and in the case of a fault on the operating link, the MPLS packets conducted via the protection link between the two switching devices are picked up in accordance with priority criteria by means of which it is established in the event of the simultaneous occurrence of a plurality of protection switching requests which criterion has the highest priority, and are transmitted by logical connection information included in the packet head of the MPLS packets, and are fed to the further devices of the MPLS network. This is associated with the advantage that the connection can be maintained in the case of a fault. The provision of one or more packet heads which are added to the IP packet in the MPLS network does not form a restriction in this case.

Advantageous further developments of the invention are specified in the subclaims.

In the text which follows, the invention will be explained in more detail with reference to an exemplary embodiment. In the figures:

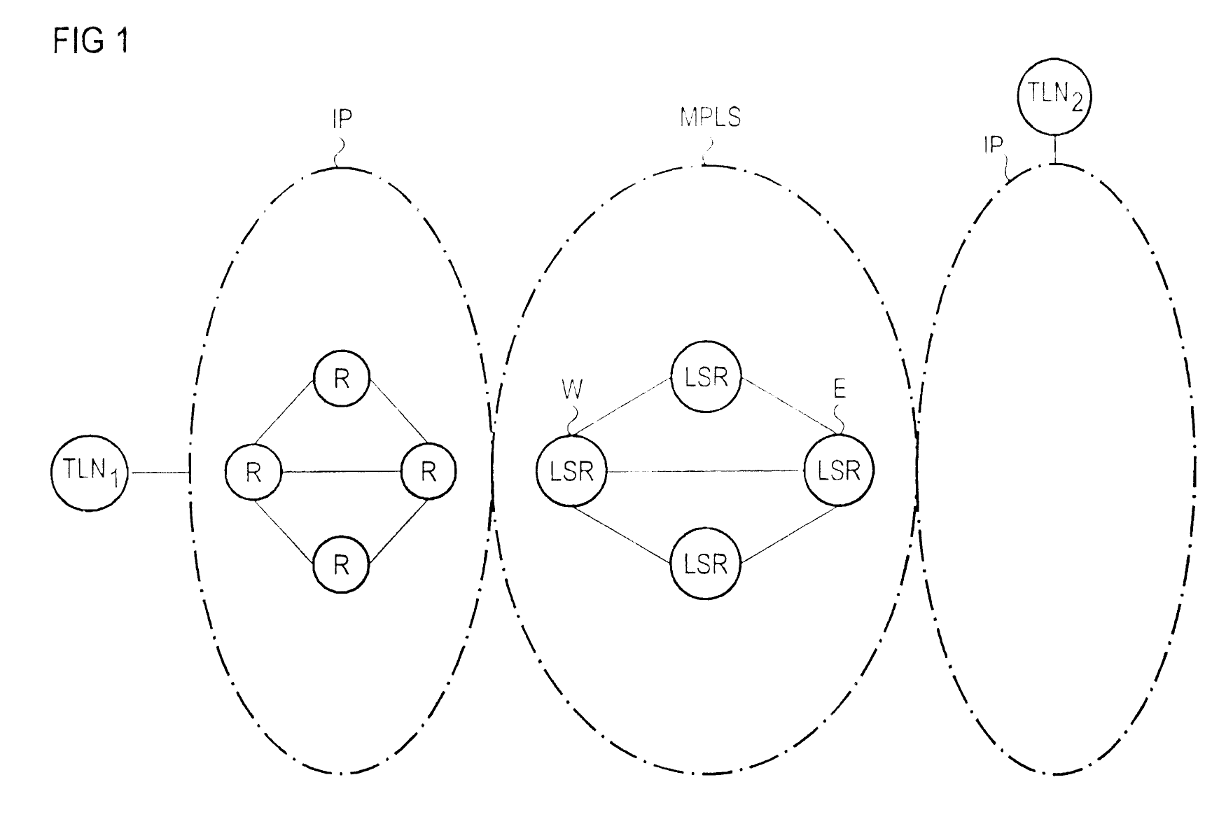

FIG. 1 shows an MPLS network linked into the Internet,

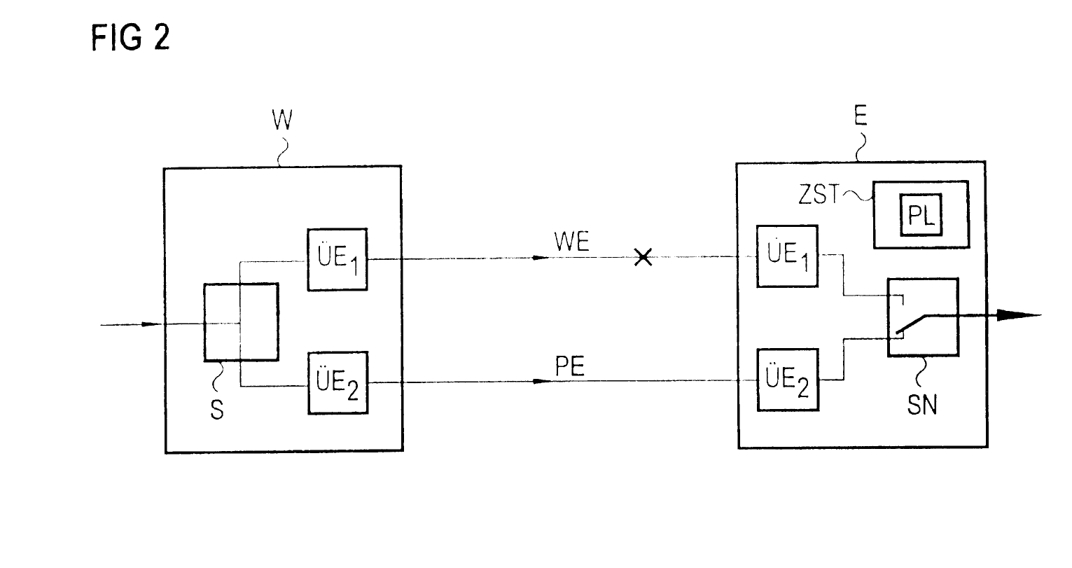

FIG. 2 shows the method according to the invention for transmitting MPLS packets in a 1+1 structure,

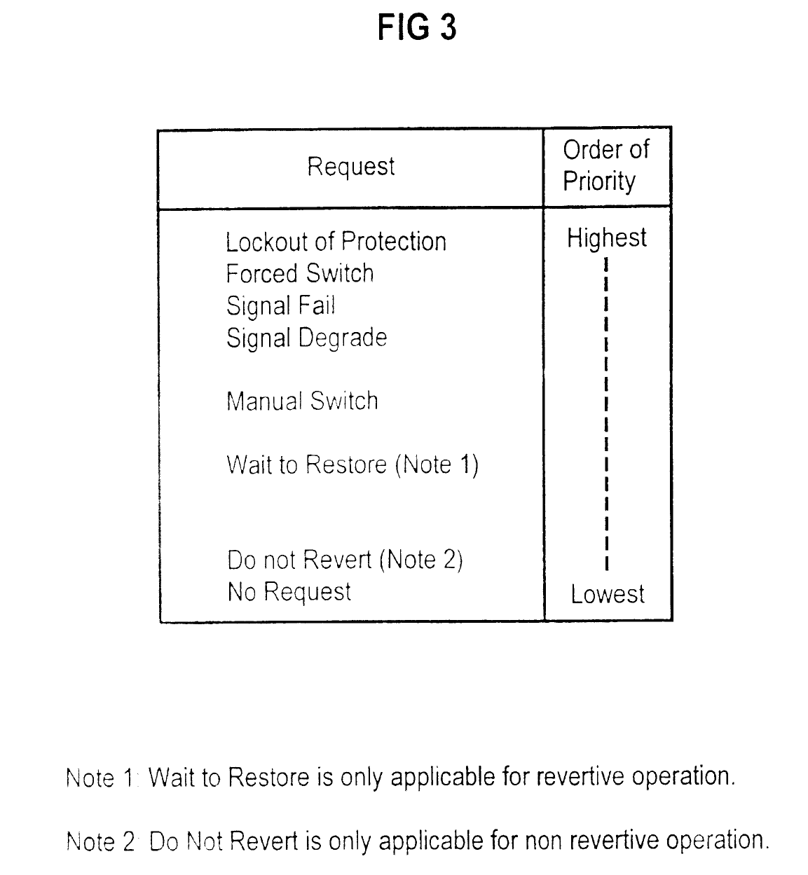

FIG. 3 shows the priorities used in accordance with which the protection switching is effected.

FIG. 1 shows for example how information coming from a subscriber TLN1 is supplied to a subscriber TLN2. The transmitting subscriber TLN1 is connected in this case to the Internet network IP through which the information is conducted in accordance with an Internet protocol such as, for example, the IP protocol. This protocol is not a connection-oriented protocol. The Internet network IP exhibits a multiplicity of routers R which can be intermeshed with one another. The receiving subscriber TLN2 is connected to a further Internet network IP. Between the two Internet networks IP, an MPLS (MultiProtocol Packet Label Switching) network is inserted through which information is switched through in a connection-oriented manner in the form of MPLS packets. This network exhibits a multiplicity of mutually intermeshed routers. In an MPLS network, these can be so-called label switched routers (LSR). One of the routers is designated as transmitting device W and another one is designated as receiving device E.

MPLS packets in each case have a header and an information section. The header is used for accommodating connection information whereas the information section is used for accommodating user information. The user information used is IP packets. The connection information contained in the header is constructed as MPLS connection number. However, this only has validity in the MPLS network. When, thus, an IP packet from the Internet network IP penetrates into the MPLS network, the header valid in the MPLS network is appended to it. This contains all connection information which predetermines the path of the MPLS packet in the MPLS network. If the MPLS packet leaves the MPLS network, the header is removed again and the IP packet is routed further as determined by the IP protocol in the Internet network IP following it.

The structure of the MPLS network is shown in more detail in FIG. 2. Two nodes of an MPLS network are disclosed here by way of example. This can be a unidirectional 1+1 structure. The two nodes constitute a switching device and are constructed as routers (Label Switched Router, LSR) W, E. In the present exemplary embodiment, it is assumed that these routers are MPLS cross-connect switching devices. Using routers of such a construction, however, does not signify a restriction of the invention, and other switching devices such as, for example, ATM switching devices can similarly be used. In FIG. 2, MPLS packets (MultiProtocol Label Switched Packets) are then to be transmitted from the label switched router W to the label switched router E. By definition, no return direction is provided in the case of MPLS networks.

The label switched routers W, E are connected to one another via an operating link WE (WORKING ENTITY) and a protection link PE (PROTECTION ENTITY). At the transmitting end, a switching system S (BRIDGE) is shown via which incoming MPLS packets in the label switched router W are duplicated and are transmitted toward the label switched router E both via the associated operating link WE and the protection link PE. The protection link PE therefore serves as protection path for the MPLS packets conducted via the operating link WE. Setting up the protection path is optional.

Furthermore, there is disclosed in the receiving label switched router E a selection device SN, the task of which is to supply the MPLS packets transmitted via the operating link WE to the output of the label switched router E. Furthermore, monitoring devices ÜE₀, ÜE₁ (PROTECTION DOMAIN SINK, PROTECTION DOMAIN SOURCE) are shown here which monitor the state or the quality of the MPLS packets conducted via the operating link WE and the protection link PE. The monitoring devices ÜE E₀, ÜE₁ are likewise arranged in the label switched router W at the transmitting end. For example, before they are transmitted toward the label switched router E via the operating link WE, MPLS packets can be provided with control information in the monitoring device ÜE₁ of the label switched router W. This co-conducted control information is then extracted and checked at the receiving end by the monitoring device ÜE₁ of the receiving label switched router E. Using this control information, it is then possible to determine, for example, whether the transmission of the MPLS packet has been correct or not. In particular, a possible total failure (SIGNAL FAIL FOR WORKING ENTITY) of the operating link WE can be determined here. Similarly, degradations in the transmission quality (SIGNAL DEGRADE) however can also be determined by using known methods. The monitoring devices ÜE₀, ÜE₁ terminate the operating link WE and protection link PE at both ends. The protection link PE is intended in the case of a fault to serve as transmission link for the operating link WE taken out of operation.

In each label switched router W, E, central controllers ZST are also arranged. These contain priority tables PL in each case. These are local priority tables in which status and priority of the local label switched router are stored. The introduction of the priorities has the result that when a plurality of protection switching requests occur at the same time, it is specified which protection switching request is to be used in the prioritized manner. Thus, for example, there exists a high-priority request from a user. Since this protection switching request is assigned a high priority, it is therefore preferentially controlled. A protection switching request of lower priority than others is therefore rejected. The individual priorities are shown in tabular form in FIG. 3.

The carrying out of the method according to the invention will now be explained in more detail below. It is firstly assumed in the case of the configuration according to FIG. 2 that each MPLS connection is monitored individually and protection-switched individually. Failures and faults can therefore be taken into account individually in terms of connections. The MPLS packets are transmitted from the label switched router W toward the label switched router E via the operating link WE and the protection link PE. Initially, the operating link WE is still intact and the MPLS packets are supplied via it correctly to the receiving label switched router E. The MPLS packets belong to one or more connections which are conducted physically via the same operating link WE and which in each case can have a protection path (optional) via the protection link PE. The individual connections are distinguished with the aid of the logical MPLS connection number entered in the header of the MPLS packets.

The switching system S of the label switched router W duplicates the incoming MPLS packets and transfers them to the monitoring devices ÜE₀, ÜE₁. Here, the MPLS packets are loaded with the control information already addressed and supplied via the operating link WE and the protection link PE to the receiving label switched router E. At the input end, the monitoring devices ÜE₀, ÜE₁ are arranged there. The co-conducted control information is now checked, whereupon the case of a fault is determined, if appropriate. If the transmission is effected correctly, the MPLS packets are supplied to a switching array SN.

It is now assumed below that the operating link WE has failed. This is determined by the monitoring device ÜE₁ of the receiving label switched router E. A protection switching request generated for this purpose is now transferred to the relevant central controller ZST of the receiving label switched router E and filed there in the local priority table PL kept here

It is now determined in accordance with the priorities stored in the local priority table PL whether there are even higher-priority requests. This could be, for example, the already addressed switchover request from the user (FORCED SWITCH). The priorities stored in the local priority table PL are shown in FIG. 3. If no requests of higher priority are present, the switching system SN of the label switched router E is controlled into the remaining operating state, as shown in FIG. 1. The MPLS packets conducted via the protection link PE are picked up and supplied to the switching array SN, and the operating link WE is taken out of operation.

It has so far been assumed that each MPLS connection is monitored and protection-switched individually. Consequently, failures and faults can be taken into account individually in terms of connection in such a way that in the event of failure or degradation of the transmission quality of a single connection the latter can be protection-switched.

In practical designs of transmission devices of this type, however, many individual connections are frequently conducted via the same physical path (for example a glass fiber) between transmission devices. In the case of an interruption of this path (for example glass fiber breakage), all the individual connections are then affected by a single failure. In practice, failures of this type outweigh failures which affect only individual connections. In particular, it would be necessary in this case to enter a protection switching protocol in the priority table PL for each interrupted individual connection.

In a refinement of the invention, it is therefore provided to protection-switch a multiplicity of individual connections jointly by means of group protection switching.

For this purpose, all MPLS connections conducted via the same physical path are logically combined to form a group. Furthermore, 2 protection switching connections are created for this group. The first of these protection switching connections is conducted via the operating link WE (MPLS protection switching LSP; LSP=Label Switched Path), as a result of which it is conducted via the same physical path between the label switched routers W and E, like all associated individual connections. The second of these protection switching connections is set up via the protection link PE.

In the group protection switching-method, it is now only these two protection switching connections that are still monitored in the monitoring devices ÜE₁, ÜE₀ for failures and faults. The individual connections are no longer monitored. In the case of a protection switching request, the priority-controlled protection switching decision is taken, as previously, in the priority logic PL. In the case of protection switching, however, all individual connections belonging to a group are switched over jointly by the switching system SN.

It is advantageous here that a multiplicity of individual connections can be monitored and protection-switched by a single protection switching connection, in order thereby to be able to react appropriately to the faults occurring most frequently in practical operation. Furthermore, only one protection switching protocol is entered in the priority table PL.

The operating and protection links WE and PE must be set up before commissioning. For this purpose, connections must be set up (configured) between the label switched routers W and E, as well as, if appropriate, at transmission devices therebetween (not illustrated in FIG. 3).

The setting up of these connections is usually effected by TMN (telecommunications network management), but can also be effected by means of an MPLS signaling protocol. For this purpose, the path of the operating or protection link is established in this case by signaling. In addition, the signaling protocol is used to reserve bandwidth in the transmission devices, thus ensuring the transmission of the information via the operating link or protection link.

1. A method for the protection switching of transmission devices in MPLS networks, comprising two switching devices (W, E), which in each case terminate a transmission section formed from an operating link (WE) and a protection link (PE), it being possible for further switching devices to be arranged in the transmission section, and one of the switching devices (W) feeding information in MPLS packets to the remaining switching device (E) via the transmission section, and there being provided monitoring devices (ÜE₀, ÜE₁) which are arranged in each case at the end of the transmission section and by which a fault are determined on the transmission section,
characterized
in that the MPLS packets are additionally conducted via the protection link (PE), in that in the case of a fault on the operating link (WE), the MPLS packets conducted via the protection link (PE) between the two switching devices (W, E) are picked up in accordance with priority criteria by means of which it is established in the event of the simultaneous occurrence of a plurality of protection switching requests which criterion has the highest priority, and are transmitted by logical connection information included in the packet head of the MPLS packets, and are fed to further devices of the MPLS network.

2. The method as claimed in claim 1,
characterized
in that a protection switching request which is assigned further priorities is generated in the case of protection switching.

3. The method as claimed in claim 1, 2,
characterized
in that the logical connection information is the MPLS connection number (label value).

4. The method as claimed in claims 1 to 3,
characterized
in that the protection switching request per failed MPLS connection are stored in priority tables (PL).

5. The method as claimed one of claims 1 to 4,
characterized
in that the protection switching is effected by driving a selection device (SN) arranged in the receiving switching device.

6. The method as claimed in one of the preceding claims,
characterized
in that total failure and degradation of an operating link are determined in the monitoring device of the receiving switching device.

7. The method as claimed in one of the preceding claims,
characterized
in that group protection switching is provided in that all MPLS connections conducted via the same physical path are logically combined to form a group, and for the group formed in this manner two protection switching connections are generated, the first of these protection switching connections being set up via the operating link (WE) and the second of these protection switching connections being set up via the protection link (PE).

8. The method as claimed in one of the preceding claims,
characterized
in that in the case where group protection switching is provided, the monitoring devices (ÜE₀, ÜE₁) only monitor the two protection switching connections.

9. The method as claimed in one of the preceding claims,
characterized
in that the connections conducted via the operating link (WE) and the protection link are set up via an MPLS signaling protocol which reserves bandwidth in the transmission devices and specifies the path of the operating link (WE) and the protection link (PE).

10. The method as claimed in one of the preceding claims,
characterized
in that the switching devices (W, E) are constructed as cross-connect switching systems.
